(19) United States
(12) Patent Application Publication
(10) Pub. No.: US 2013/0148297 A1
(43) Pub. Date: Jun. 13, 2013

(54) ELECTRONIC DEVICE WITH AIR DUCT

(71) Applicant: CHAO-KE WEI, Tu-Cheng (TW)

(72) Inventor: CHAO-KE WEI, Tu-Cheng (TW)

(73) Assignee: HON HAI PRECISION INDUSTRY CO., LTD., Tu-Cheng (TW)

(21) Appl. No.: 13/337,257

(22) Filed: Dec. 26, 2011

(30) Foreign Application Priority Data
Dec. 12, 2011 (TW) 100145841

(51) Int. Cl. H05K 7/20; F16L 3/00

(52) U.S. Cl. 361/695; 138/106

(57) ABSTRACT

An air duct is installed in a chassis. The chassis includes a bottom wall. The air duct includes a first positioning plate and a second positioning plate perpendicularly fixed on the bottom wall and parallel to each other, and a cover. The cover includes a top plate with a first side rotatably connected to the first positioning plate, and a second side detachably latched to the second positioning plate, and the easily-removable air duct is fashioned so as to direct one or more airflows more effectively over the electronic components within an electronic device.

### BACKGROUND

1. Technical Field

The disclosure relates to the cooling of electronic devices and, particularly, to an electronic device with an air duct for guiding airflow.

2. Description of Related Art

Central processing units (CPUs) and memory cards generate a great deal of heat. The heat needs to be dissipated immediately to ensure the continued proper function of the electronic devices. A cooling fan is provided to generate airflow, and an air duct guides the airflow. The air duct is ordinarily fixed on a motherboard of an electronic device by a plurality of screws. However, it is time-consuming and often difficult to assemble or disassemble the air duct to or from the motherboard.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric, exploded view of an embodiment of an electronic device, wherein the electronic device includes an air duct.

FIG. 2 is an enlarged view of a part of the air duct of FIG. 1.

FIG. 3 is an assembled, isometric view of the electronic device of FIG. 1.

FIG. 4 is similar to FIG. 3, but showing the electronic device in a state of use.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

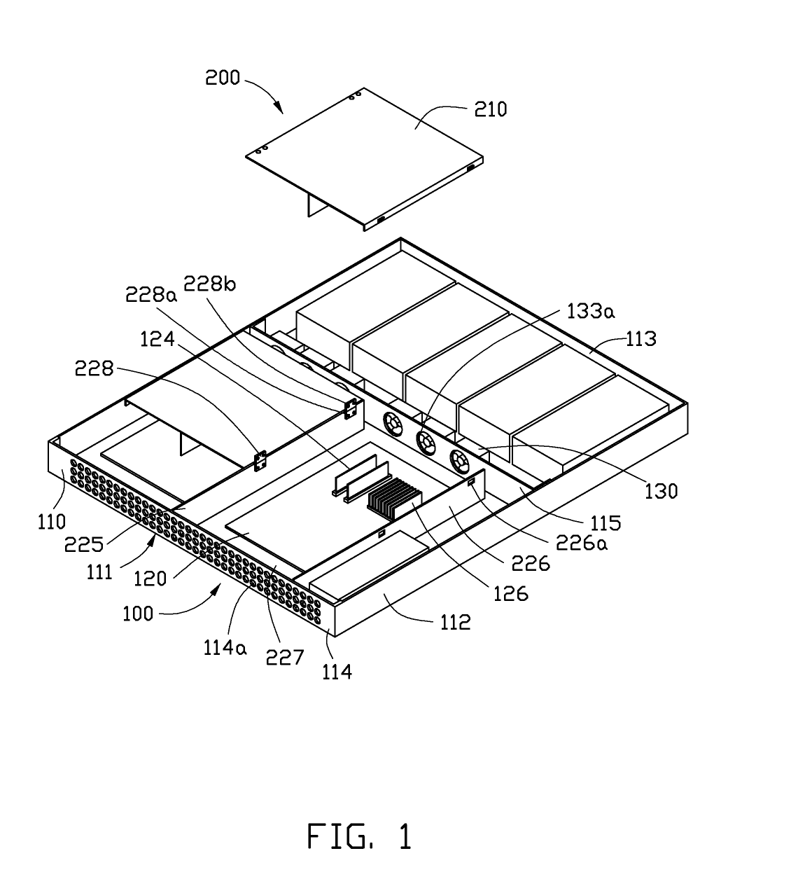

FIG. 1 shows an embodiment of an electronic device including a chassis 100 and an air duct 200.

The chassis 100 includes a rectangular shell 110, a motherboard 120 received in the shell 110, and a plurality of fans 130 received in the shell 110. The shell 110 includes a bottom wall 111, two sidewalls 112 perpendicularly extending up from two opposite sides of the bottom wall 111, a first end wall 113 perpendicularly extending up from a first end of the bottom wall 111 and connected between first ends of the sidewalls 112, and a second end wall 114 perpendicularly extending up from a second end of the bottom wall 111 and connected between second ends of the sidewalls 112. A partition plate 115 extends from the bottom wall 111, perpendicularly connected between the sidewalls 112. The partition plate 115 defines a plurality of circular through holes 133a facing the second end wall 114. The second end wall 114 defines a plurality of vents 114a.

The air duct 200 includes a cover 210, a first positioning plate 225 perpendicularly fixed on the bottom wall 111, and a second positioning plate 226 perpendicularly fixed on the bottom wall 111. The first and second positioning plates 225 and 226 are located between the sidewalls 112, and parallel to the sidewalls 112. The first and second positioning plate 225 and 226 cooperatively bound a receiving space 227.

Two hinges 228 are used to mount the air duct 200 to the chassis 100. Each hinge 228 includes a first connection portion 228a fixed to an upper portion of the first positioning plate 225, and a second connection portion 228b pivotably mounted to the first connection portion 228a. The second positioning plate 226 defines two latching holes 226a in an upper portion.

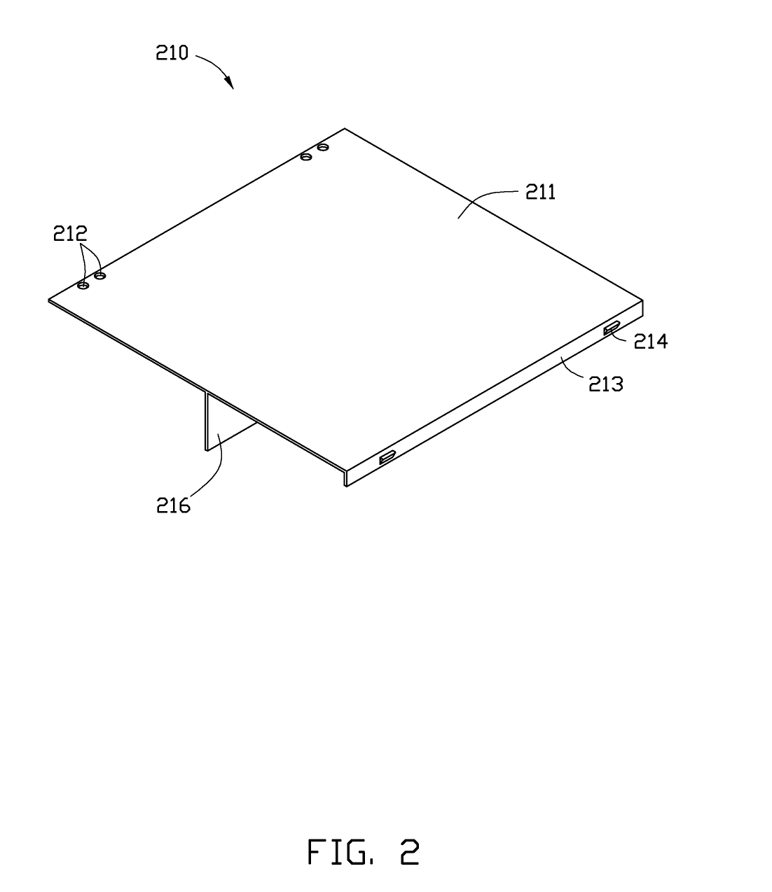

Referring to FIG. 2, the cover 210 includes a top plate 211, a fixing piece 213 perpendicularly extending down from a first side of the top plate 211, and a partition plate 216 extending down from the top plate 211 and parallel to the fixing piece 213. A second side of the top plate 211 opposite to the first side defines two groups of fastening holes 212. Two protrusions 214 protrude out from the fixing piece 213.

The motherboard 120 is received in the receiving space 227, and fixed on the bottom wall 111. A first component 124 and a second component 126 are positioned on the motherboard 120. In the embodiment, the first component 124 is a memory card, and the second component 26 is a heat sink. The fans 130 are attached to a surface of the partition plate 115 opposite to the second end wall 114, aligning with the through holes 133a.

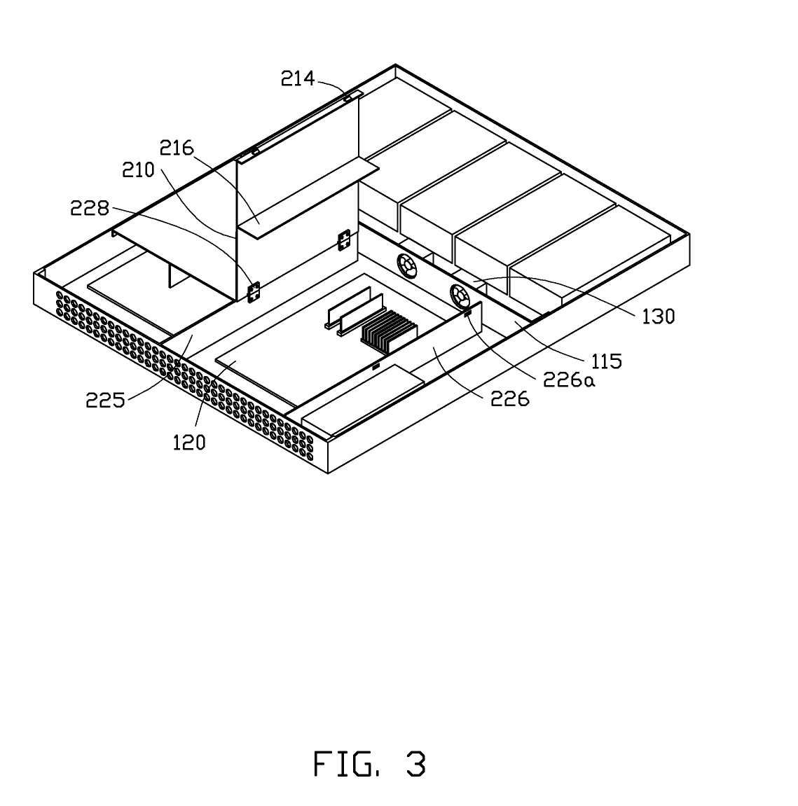

Referring to FIG. 3, in assembly of the cover 210 to the chassis 100, screws extend through the second connection portions 228b of the hinges 228, to be screwed into the fastening holes 212 of the cover 210. Therefore, the cover 210 can rotate relative to the first positioning plate 225 by means of the hinges 228. The partition plate 216 faces the motherboard 120.

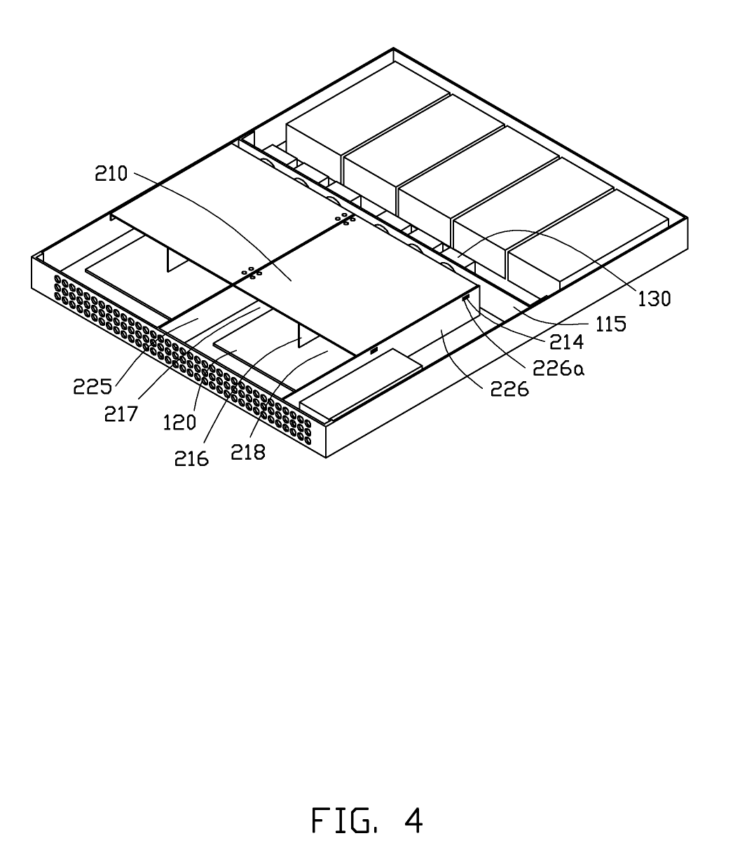

Referring to FIG. 4, in use, the cover 210 is rotated down, to allow the protrusions 214 to latch into the latching holes 226a, creating a hollow box. A side of the partition plate 216 opposite to the top plate 211 abuts against the motherboard 120, between the first component 124 and the second component 126. The first positioning plate 225 and the partition plate 216 cooperatively bound a first airflow channel 217 for receiving the first component 124. The second positioning plate 226 and the partition plate 216 cooperatively bound a second airflow channel 218 for receiving the second component 126. The air flows in a directed and particular manner through the first and second airflow channels 217 and 218, so as to dissipate the heat of the first and second components 124 and 126 more effectively.

When the first component 124 or the second component 126 needs to be repaired or replaced, the protrusions 214 are disengaged from the latching holes 226a, and the cover 200 is rotated away from the motherboard 120 to totally expose the first and second components 124 and 126.

It is to be understood, however, that even though numerous characteristics and advantages of certain embodiments have been set forth in the foregoing description, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An air duct installed in a chassis, and comprising:
a first positioning plate fixed in the chassis;
a second positioning plate opposite to the first positioning plate and fixed in the chassis; and
a cover comprising a top plate with a first side rotatably connected to the first positioning plate, and a second side detachably latched to the second positioning plate.

2. The air duct of claim 1, further comprising a hinge connected between the first side of the cover and the first positioning plate, wherein the cover is rotatable relative to the first positioning plate via the hinge.

3. The air duct of claim 1, wherein a partition plate extends down from the top plate, the first positioning plate and the partition plate cooperatively bound a first airflow channel, the second positioning plate and the partition plate cooperatively bound a second airflow channel.

4. The air duct of claim 1, wherein a fixing piece extends down from the second side of the top plate, a protrusion extends from the fixing piece to be detachably latched to the second positioning plate.

5. An electronic device, comprising:
a chassis comprising a bottom wall;
an air duct comprising a first positioning plate fixed on the bottom wall, a second positioning plate opposite to the first positioning plate and fixed on the bottom wall, and a cover with a first side rotatably connected to the first positioning plat, and a second side detachably latched to the second positioning plate;
a motherboard supported on the bottom wall between the first positioning plate and the second positioning plate, and comprising a plurality of components; and
a fan aligning with the components and located between the first and second positioning plates.

6. The electronic device of claim 5, further comprising a hinge connected between the first side of the cover and the first positioning plate, wherein the cover is rotatable relative to the first positioning plate via the hinge.

7. The electronic device of claim 5, wherein the second positioning plate defines a latching hole, a fixing piece extends down from the second side of the cover, a protrusion protrudes out from the fixing piece to be detachably latched to the latching hole.

8. The electronic device of claim 5, wherein a partition plate extends down from the top plate, the first positioning plate and the partition plate cooperatively bound a first airflow channel for receiving some of the components, the second positioning plate and the partition plate cooperatively bound a second airflow channel for receiving the other components.
